(19) United States
(12) Patent Application Publication
(10) Pub. No.: US 2026/0047006 A1
(43) Pub. Date: Feb. 12, 2026

(54) SUBSTRATE STRUCTURE AND MANUFACTURING METHOD THEREOF

(71) Applicant: Unimicron Technology Corp., Taoyuan City (TW)

(72) Inventors: Chin-Sheng Wang, Taoyuan City (TW); Chih-Kai Chan, Taoyuan City (TW); Shih-Lian Cheng, New Taipei City (TW); Ra-Min Tain, Hsinchu County (TW); Guang-Hwa Ma, Hsinchu City (TW)

(73) Assignee: Unimicron Technology Corp., Taoyuan City (TW)

(21) Appl. No.: 19/021,236

(22) Filed: Jan. 15, 2025

Related U.S. Application Data
(60) Provisional application No. 63/680,613, filed on Aug. 8, 2024.

(30) Foreign Application Priority Data
Nov. 14, 2024 (TW) 113143739

(51) Int. Cl. H05K 1/11; H05K 3/18; H05K 3/40

(52) U.S. Cl. CPC H05K 1/115; H05K 3/181; H05K 3/4038; H05K 2201/09509

(57) ABSTRACT

A substrate structure, including a core substrate, a sputtered metal layer, an electroless metal layer, and a conductive material layer. The core substrate has an upper surface, a lower surface, and at least one through-hole penetrating from the upper surface to the lower surface. The sputtered metal layer is configured on the upper surface, the lower surface, and a portion of an inner wall of the through-hole of the core substrate. The electroless metal layer is configured on the sputtered metal layer and a remaining portion of the inner wall of the through-hole. The conductive material layer is configured on the electroless metal layer and fills the through-hole to define at least one first conductive circuit on the upper surface, at least one second conductive circuit on the lower surface, and at least one conductive through-hole located in the through-hole and electrically connected to the first and second conductive circuits.

### CROSS-REFERENCE TO RELATED APPLICATION

This application claims the priority benefit of U.S. provisional application Ser. No. 63/680,613, filed on Aug. 8, 2024, and Taiwan application serial no. 113143739, filed on Nov. 14, 2024. The entirety of each of the above-mentioned patent applications is hereby incorporated by reference herein and made a part of this specification.

### BACKGROUND

### Technical Field

The disclosure relates to a substrate structure and a manufacturing method thereof, and in particular to a substrate structure and a manufacturing method thereof that enhance structural reliability.

### Description of Related Art

Generally, due to the issue of adhesion between inorganic substrates and metal layers, metal layers are deposited on inorganic substrates using dry deposition methods (e.g., physical vapor deposition (PVD) or chemical vapor deposition (CVD)). However, forming metal layers through dry deposition is relatively costly, and for blind vias and through-holes with high aspect ratios, the dry deposition process often encounters the problem of low step coverage. This issue increases process defects and reduces product reliability.

### SUMMARY

The disclosure provides a substrate structure having an improved structural reliability.

The disclosure further provides a manufacturing method of the substrate structure so as to manufacture the substrate structure.

A substrate structure of the disclosure includes a core substrate, a sputtered metal layer, an electroless metal layer, and a conductive material layer. The core substrate has an upper surface and a lower surface opposite to each other, and at least one through-hole penetrating from the upper surface to the lower surface. The sputtered metal layer is configured on the upper surface, the lower surface, and a portion of an inner wall of the at least one through-hole of the core substrate. The electroless metal layer is configured on the sputtered metal layer and a remaining portion of the inner wall of the at least one through-hole. The conductive material layer is configured on the electroless metal layer and fills the at least one through-hole, defining at least one first conductive circuit on the upper surface, at least one second conductive circuit on the lower surface, and at least one conductive through-hole located in the at least one through-hole and electrically connected to the at least one first conductive circuit and the at least one second conductive circuit.

In an embodiment of the disclosure, the substrate structure further includes an adhesion promotion layer, directly covering the upper surface, the lower surface, and the inner wall of the at least one through-hole of the core substrate. The sputtered metal layer is located between the adhesion promotion layer and the electroless metal layer.

In an embodiment of the disclosure, a material of the adhesion promotion layer includes an oxide or a nitride.

In an embodiment of the disclosure, the oxide includes a silicon oxide, an aluminum oxide, or a titanium oxide.

In an embodiment of the disclosure, the nitride includes a silicon nitride.

In an embodiment of the disclosure, a thickness of the adhesion promotion layer is between 0.01 nanometers and 100 nanometers.

In an embodiment of the disclosure, the core substrate includes an insulating substrate.

In an embodiment of the disclosure, the insulating substrate includes an inorganic substrate.

In an embodiment of the disclosure, a material of the inorganic substrate includes a glass or a ceramic.

In an embodiment of the disclosure, a surface roughness of the core substrate is between 1 nanometer and 50 nanometers.

In an embodiment of the disclosure, a thickness of the core substrate is between 50 micrometers and 1000 micrometers.

In an embodiment of the disclosure, a diameter of the at least one through-hole is between 10 micrometers and 200 micrometers.

In an embodiment of the disclosure, a thickness of the electroless metal layer is less than 1 micrometer.

In an embodiment of the disclosure, a material of the electroless metal layer includes a nickel-phosphorus, a copper, a silver, or a combination thereof.

In an embodiment of the disclosure, a material of the sputtered metal layer includes a titanium-copper alloy.

In an embodiment of the disclosure, the substrate structure further includes at least one build-up structure configured on at least one of the upper surface and the lower surface of the core substrate. The at least one build-up structure includes at least one insulating layer, at least one conductive blind via, and at least one circuit. The at least one insulating layer covers at least one of the at least one first conductive circuit and the at least one second conductive circuit. The at least one circuit is located on the at least one insulating layer. The at least one conductive blind via is located in the at least one insulating layer and is electrically connected to the at least one circuit and at least one of the at least one first conductive circuit and the at least one second conductive circuit.

A manufacturing method of a substrate structure of the disclosure includes the following steps. A core substrate is provided. The core substrate has an upper surface and a lower surface opposite to each other, and at least one through-hole penetrating from the upper surface to the lower surface. A dry process is performed on the core substrate to form a sputtered metal layer on the upper surface, the lower surface, and a portion of an inner wall of the at least one through-hole of the core substrate. A wet process is performed on the core substrate to form an electroless metal layer on the sputtered metal layer and a remaining portion of the inner wall of the at least one through-hole. A conductive material layer is formed on the electroless metal layer and fills the at least one through-hole, defining at least one conductive through-hole in the at least one through-hole. The conductive material, the electroless metal layer, and the sputtered metal layer are patterned to define at least one first conductive circuit on the upper surface of the core substrate and at least one second conductive circuit on the lower surface of the core substrate. The at least one conductive through-hole is electrically connected to the at least one first conductive circuit and the at least one second conductive circuit.

In an embodiment of the disclosure, the manufacturing method of the substrate structure further includes the following step. An adhesion promotion layer directly covering the upper surface, the lower surface, and the inner wall of the at least one through-hole of the core substrate is formed before the dry process is performed on the core substrate.

In an embodiment of the disclosure, a material of the adhesion promotion layer includes an oxide or a nitride.

In an embodiment of the disclosure, the manufacturing method of the substrate structure further includes the following steps. After patterning the conductive material, the electroless metal layer, and the sputtered metal layer, at least one build-up structure is formed on at least one of the upper surface and the lower surface of the core substrate. The at least one build-up structure includes at least one insulating layer, at least one conductive blind via, and at least one circuit. The at least one insulating layer covers at least one of the at least one first conductive circuit and the at least one second conductive circuit. The at least one circuit is located on the at least one insulating layer. The at least one conductive blind via is located in the at least one insulating layer and is electrically connected to the at least one circuit and at least one of the at least one first conductive circuit and the at least one second conductive circuit.

Based on the above, in the substrate structure and the manufacturing method thereof of the disclosure, the sputtered metal layer is formed on the upper surface, the lower surface, and a portion of the inner wall of the through-hole of the core substrate through a dry process. Subsequently, the electroless metal layer is formed on the sputtered metal layer and a remaining portion of the inner wall of the through-hole through a wet process. This approach addresses the issue of low step coverage encountered in the dry deposition process in the prior art, thereby allowing the substrate structure of the disclosure to have improved structural reliability.

To make the features and advantages of the disclosure more comprehensible, several embodiments accompanied with drawings are described in detail as follows.

### BRIEF DESCRIPTION OF THE DRAWINGS

FIGS. 1A to 1D are cross-sectional schematic diagrams of a manufacturing method of a substrate structure according to an embodiment of the disclosure.

FIG. 2 is a cross-sectional schematic diagram of a substrate structure according to an embodiment of the disclosure.

FIGS. 3A to 3D are cross-sectional schematic diagrams of partial steps of a manufacturing method of a substrate structure according to another embodiment of the disclosure.

FIG. 4 is a cross-sectional schematic diagram of a substrate structure according to another embodiment of the disclosure.

### DESCRIPTION OF THE EMBODIMENTS

The embodiments of the disclosure can be understood together with the drawings, and the drawings of the disclosure are also regarded as a part of the disclosure description. It is to be understood that the drawings of the disclosure are not to scale and, in fact, the dimensions of elements may be arbitrarily enlarged or reduced in order to clearly represent the features of the disclosure.

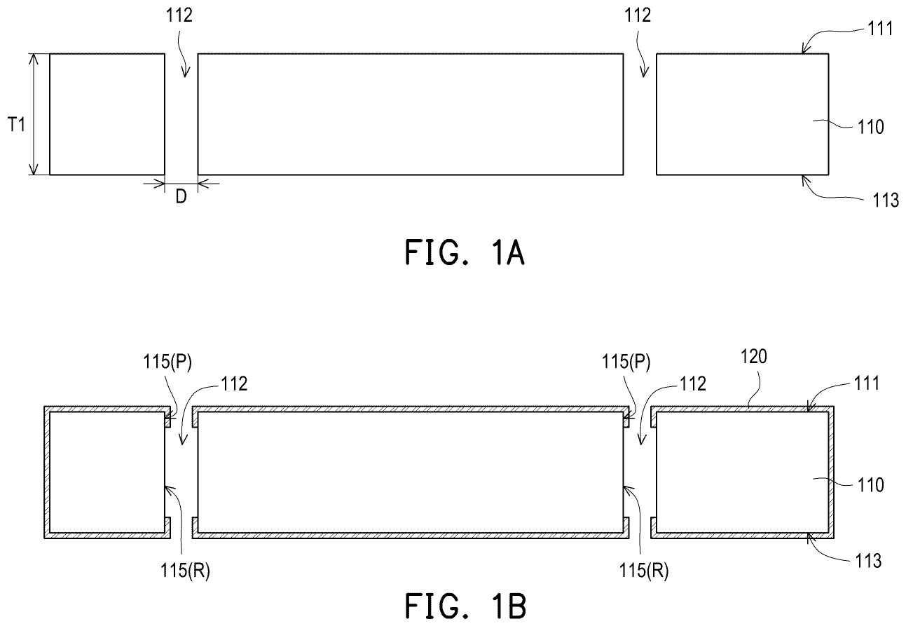

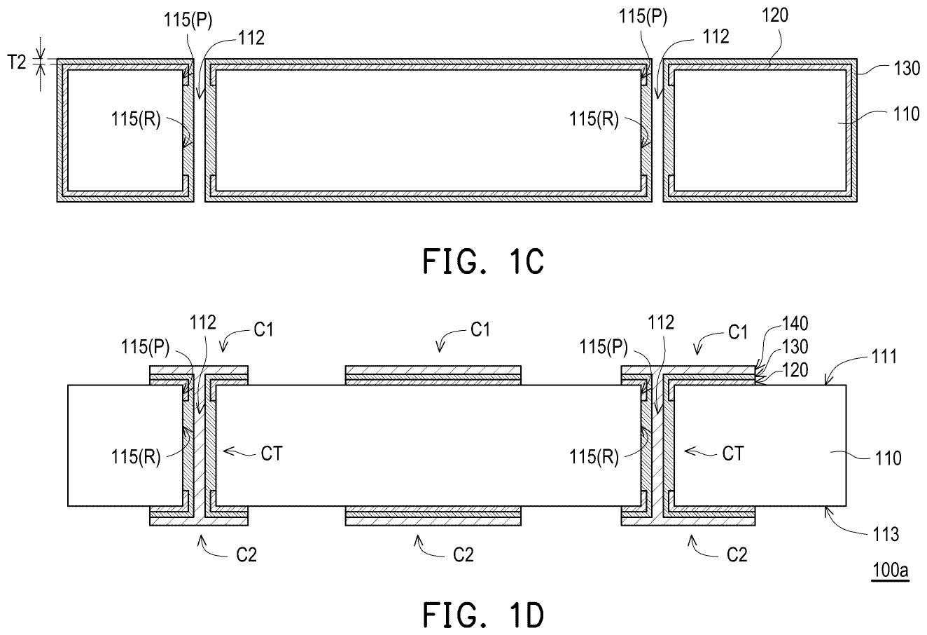

FIGS. 1A to 1D are cross-sectional schematic diagrams of a manufacturing method of a substrate structure according to an embodiment of the disclosure. According to the manufacturing method of the substrate structure in this embodiment, referring first to FIG. 1A, a core substrate 110 is provided. The core substrate 110 has an upper surface 111 and a lower surface 113 opposite to each other, and at least one through-hole (two through-holes 112 are schematically illustrated) penetrating from the upper surface 111 to the lower surface 113. In an embodiment, the core substrate 110 is an insulating substrate. In an embodiment, the insulating substrate can be an inorganic substrate, and the material of the inorganic substrate can be glass or ceramic, but is not limited thereto. In this embodiment, the surface roughness (e.g., Sa) of the core substrate 110 is between 1 nanometer and 50 nanometers. Preferably, the surface roughness of the core substrate 110 is less than 10 nanometers. It should be noted that Sa is the extension of Ra (arithmetical mean height of the line) to the surface, representing the absolute value of the difference between the height of each point and the arithmetical mean value of the surface. This parameter is generally used to evaluate surface roughness. A thickness T1 of the core substrate 110 is between 50 micrometers and 1000 micrometers, and preferably, between 100 micrometers and 800 micrometers. In an embodiment, the through-hole 112 can be a through-glass vias (TGV). In an embodiment, a diameter D of the through-hole 112 is between 10 micrometers and 200 micrometers, and preferably, between 100 micrometers and 200 micrometers.

Next, referring to FIG. 1B, a dry process is performed on the core substrate 110 to form a sputtered metal layer 120 on the upper surface 111, the lower surface 113, the peripheral surface connecting the upper surface 111 and the lower surface 113, and a portion P of an inner wall 115 of the through-hole 112. Here, the sputtered metal layer 120 only covers the portion P of the inner wall 115, while a remaining portion R of the inner wall 115 is not covered by the sputtered metal layer 120. In an embodiment, the material of the sputtered metal layer 120 is a titanium-copper alloy, but is not limited thereto.

Next, referring to FIG. 1C, a wet process is performed on the core substrate 110 to form an electroless metal layer 130 on the sputtered metal layer 120 and on the remaining portion R of the inner wall 115 of the through-hole 112. In other words, in this embodiment, the inner wall 115 of the through-hole 112 is directly covered by the sputtered metal layer 120 and the electroless metal layer 130. A thickness T2 of the electroless metal layer 130 is, for example, less than 1 micrometer. In an embodiment, the material of the electroless metal layer 130 includes nickel-phosphorus, copper, silver, or a combination of these materials.

Next, referring to FIGS. 1C and 1D, using the electroless metal layer 130 as an electroplating seed layer, a conductive material layer 140 is formed on the electroless metal layer 130 by electroplating, filling the through-hole 112 and defining at least one conductive through-hole (two conductive through-holes CT are schematically illustrated).

Finally, referring again to FIG. 1D, the conductive material layer 140, the electroless metal layer 130, and the sputtered metal layer 120 are patterned to define at least one first conductive circuit (three first conductive circuits C1 are schematically illustrated) on the upper surface 111 of the core substrate 110, and at least one second conductive circuit (three second conductive circuits C2 are schematically illustrated) on the lower surface 113 of the core substrate 110. The conductive through-hole CT is electrically connected to the first conductive circuit C1 and the second conductive circuit C2. At this point, the manufacturing of a substrate structure 100a is complete.

Structurally, referring again to FIG. 1D, the substrate structure 100a in this embodiment includes the core substrate 110, the sputtered metal layer 120, the electroless metal layer 130, and the conductive material layer 140. The core substrate 110 has an upper surface 111 and a lower surface 113 opposite to each other, and the through-hole 112 penetrating from the upper surface 111 to the lower surface 113. The sputtered metal layer 120 is configured on the upper surface 111, the lower surface 113, and a portion P of the inner wall 115 of the through-hole 112 of the core substrate 110. The electroless metal layer 130 is configured on the sputtered metal layer 120 and on the remaining portion R of the inner wall 115 of the through-holes 112. The conductive material layer 140 is configured on the electroless metal layer 130 and fills the through-hole 112, defining the first conductive circuit C1 located on the upper surface 111, the second conductive circuit C2 located on the lower surface 113, and the conductive through-hole CT located in the through-hole 112 and electrically connected to the first conductive circuit C1 and the second conductive circuit C2.

In short, this embodiment first forms the sputtered metal layer 120 on the upper surface 111, the lower surface 113, and a portion P of the inner wall 115 of the through-hole 112 of the core substrate 110 through a dry process. Subsequently, a wet process is performed to form the electroless metal layer 130 on the sputtered metal layer 120 and on the remaining portion R of the inner wall 115 of the through-hole 112. This approach addresses the issue of low step coverage encountered in the dry deposition process in the prior art, thereby allowing the substrate structure 100a in this embodiment to have improved structural reliability.

The following will list other embodiments for illustration. It should be noted that the subsequent embodiments reuse the reference numerals and some content from the previous embodiment, where the same numerals are used to denote the same or similar elements, and explanations of identical technical content are omitted. For the omitted parts, reference may be made to the previous embodiment, and repetitive descriptions will not be provided here.

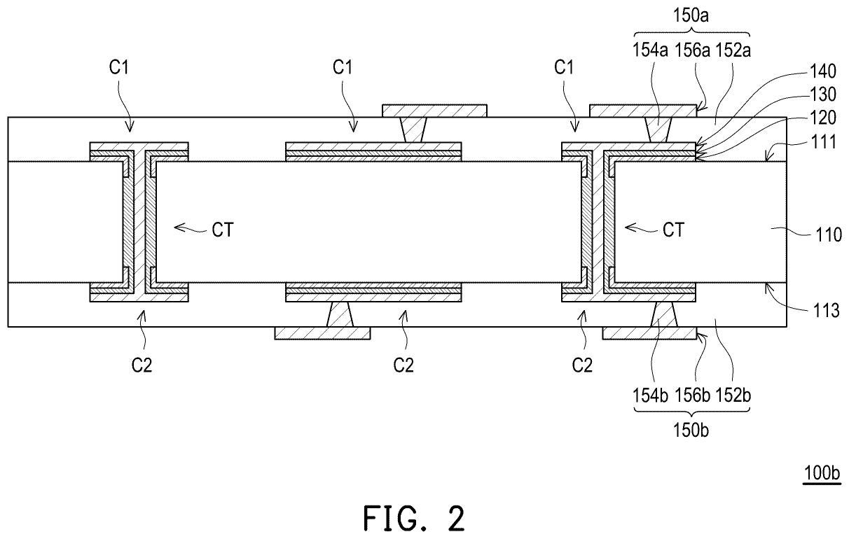

FIG. 2 is a cross-sectional schematic diagram of a substrate structure according to an embodiment of the disclosure. Referring to FIGS. 1D and 2, a substrate structure 100b in this embodiment is similar to the substrate structure 100a described above. However, the main difference between the two lies in the following. In this embodiment, after patterning the conductive material 140, the electroless metal layer 130, and the sputtered metal layer 120, at least one build-up structure (two build-up structures 150a and 150b are schematically illustrated) is formed on at least one of the upper surface 111 and the lower surface 113 of the core substrate 110 (schematically formed on the upper surface 111 and the lower surface 113, respectively). The build-up structure 150a includes at least one insulating layer (an insulating layer 152a is schematically illustrated), at least one conductive blind via (two conductive blind vias 154a are schematically illustrated), and at least one circuit (two circuits 156a are schematically illustrated). The insulating layer 152a covers the first conductive circuit C1. The circuit 156a is located on the insulating layer 152a, and the conductive blind via 154a is located in the insulating layer 152a and electrically connected to the circuit 156a and the first conductive circuit C1. Similarly, the build-up structure 150b includes at least one insulating layer (an insulating layer 152b is schematically illustrated), at least one conductive blind via (two conductive blind vias 154b are schematically illustrated), and at least one circuit (two circuits 156b are schematically illustrated). The insulating layer 152b covers the second conductive circuit C2. The circuit 156b is located on the insulating layer 152b, and the conductive blind via 154b is located in the insulating layer 152b and electrically connected to the circuit 156b and the second conductive circuit C2. Through the arrangement of the build-up structures 150a and 150b, a fan-out structure can be formed, thereby enhancing the applicability of the substrate structure 100b.

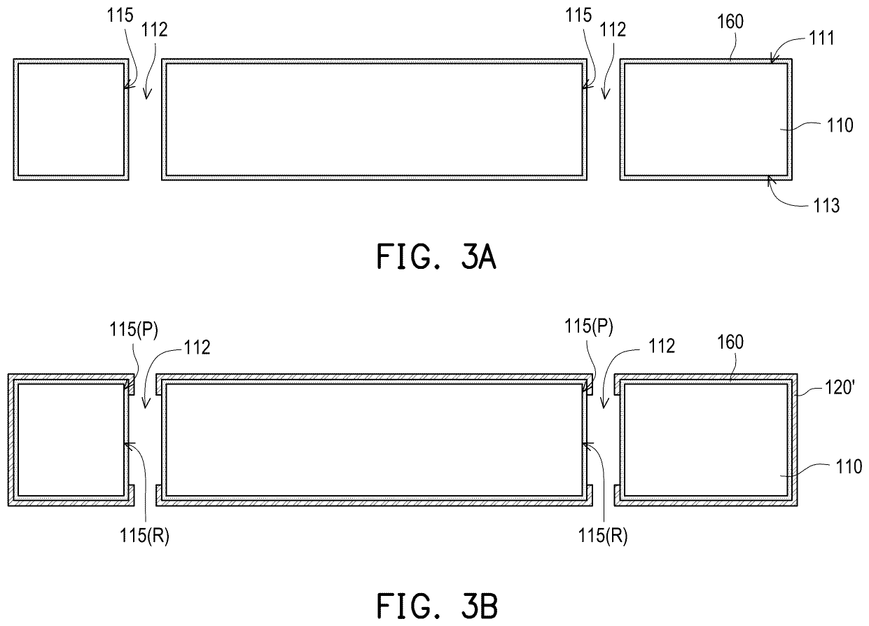

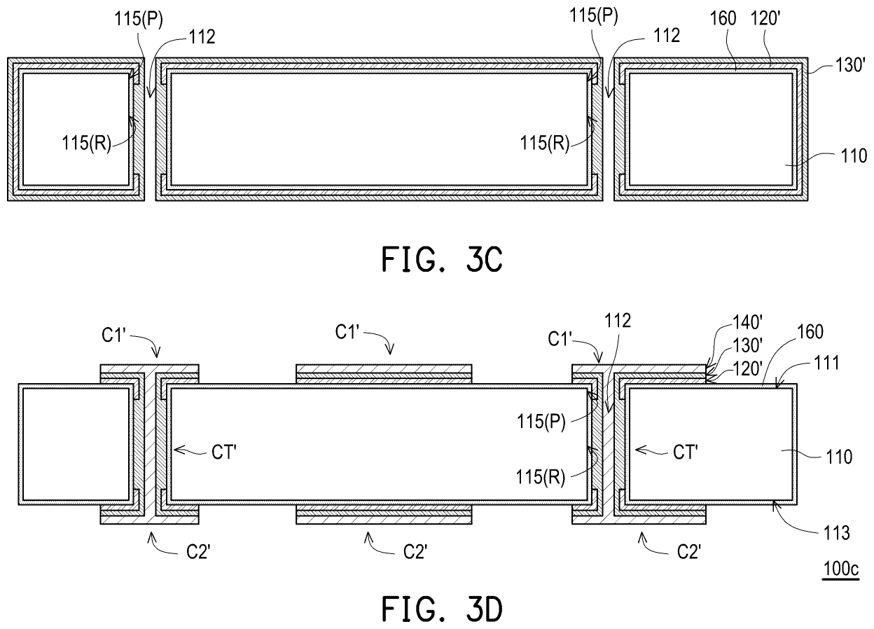

FIGS. 3A to 3C are cross-sectional schematic diagrams of partial steps of a manufacturing method of a substrate structure according to another embodiment of the disclosure. Referring to FIGS. 1B and 3A, the manufacturing method of a substrate structure 100c in this embodiment is similar to the manufacturing method of the substrate structure 100a described above. However, the main difference between the two lies in that, after the step in FIG. 1A (i.e., after providing the core substrate 110) and before the step in FIG. 1B (i.e., before performing the dry process on the core substrate 110), an adhesion promotion layer 160 is formed to directly cover the upper surface 111, the lower surface 113, the peripheral surface connecting the upper surface 111 and the lower surface 113, and the inner wall 115 of the through-hole 112 of the core substrate 110. Here, the adhesion promotion layer 160 completely covers the upper surface 111, the lower surface 113, the peripheral surface, and the inner wall 115 of the through-hole 112 of the core substrate 110. In an embodiment, the material of the adhesion promotion layer 160 includes oxides or nitrides. The oxides can include titanium oxide (TiOX) (e.g., titanium monoxide (TiO) or titanium dioxide (TiO2)), silicon oxide (SiOX) (e.g., silicon dioxide (SiO2)), or aluminum oxide (Al2O3). The nitrides can include silicon nitride (SiNX) (e.g., silicon nitride (Si3N4)). In this embodiment, the thickness T2 of the adhesion promotion layer 160 is between 0.01 nanometers and 100 nanometers. The adhesion promotion layer 160 enhances the adhesion between the core substrate 110 and the subsequently formed metal layers.

Next, referring to FIG. 3B, a dry process is performed on the core substrate 110 to form a sputtered metal layer 120′ on the upper surface 111, the lower surface 113, and a portion P of the inner wall 115 of the through-hole 112. Here, the sputtered metal layer 120′ directly covers the adhesion promotion layer 160 and only indirectly covers the portion P of the inner wall 115, while the remaining portion R of the inner wall 115 is not indirectly covered by the sputtered metal layer 120′. In an embodiment, the material of the sputtered metal layer 120′ is a titanium-copper alloy, but is not limited thereto.

Next, referring to FIG. 3C, a wet process is performed on the core substrate 110 to form an electroless metal layer 130′ on the sputtered metal layer 120′ and on the remaining portion R of the inner wall 115 of the through-hole 112. In other words, in this embodiment, the inner wall 115 of the through-hole 112 is indirectly covered by the sputtered metal layer 120′ and the electroless metal layer 130′. In an embodiment, the material of the electroless metal layer 130′ includes nickel-phosphorus, copper, silver, or a combination of these materials.

Next, referring to FIGS. 3C and 3D, using the electroless metal layer 130′ as an electroplating seed layer, a conductive material layer 140′ is formed on the electroless metal layer 130′ by electroplating, filling the through-hole 112 and defining at least one conductive through-hole (two conductive through-holes CT′ are schematically illustrated).

Finally, referring again to FIG. 3D, the conductive material layer 140′, the electroless metal layer 130′, and the sputtered metal layer 120′ are patterned to define at least one first conductive circuit (three first conductive circuits C1′ are schematically illustrated) on the upper surface 111 of the core substrate 110 and at least one second conductive circuit (three second conductive circuits C2′ are schematically illustrated) on the lower surface 113 of the core substrate 110. The conductive through-hole CT′ is electrically connected to the first conductive circuit C1′ and the second conductive circuit C2′. At this point, the manufacturing of the substrate structure 100c is complete.

Structurally, referring again to FIGS. 1D and 3D, the substrate structure 100c in this embodiment is similar to the substrate structure 100a described above. However, the main difference between the two lies in that, in this embodiment, the substrate structure 100c further includes the adhesion promotion layer 160, which directly covers the upper surface 111, the lower surface 113, and the inner wall 115 of the through-hole 112 of the core substrate 110. The sputtered metal layer 120′ is located between the adhesion promotion layer 160 and the electroless metal layer 130′.

In short, this embodiment first forms the adhesion promotion layer 160 to enhance the adhesion between the core substrate 110 and the subsequent metal layers (i.e., the sputtered metal layer 120′ and the electroless metal layer 130′). Subsequently, the sputtered metal layer 120′ is formed through a dry process, followed by the electroless metal layer 130′ being formed through a wet process on the inner wall 115 of the through-hole 112. This approach addresses the issue of low step coverage encountered in the dry deposition process in the prior art, thereby allowing the substrate structure 100c in this embodiment to have improved structural reliability.

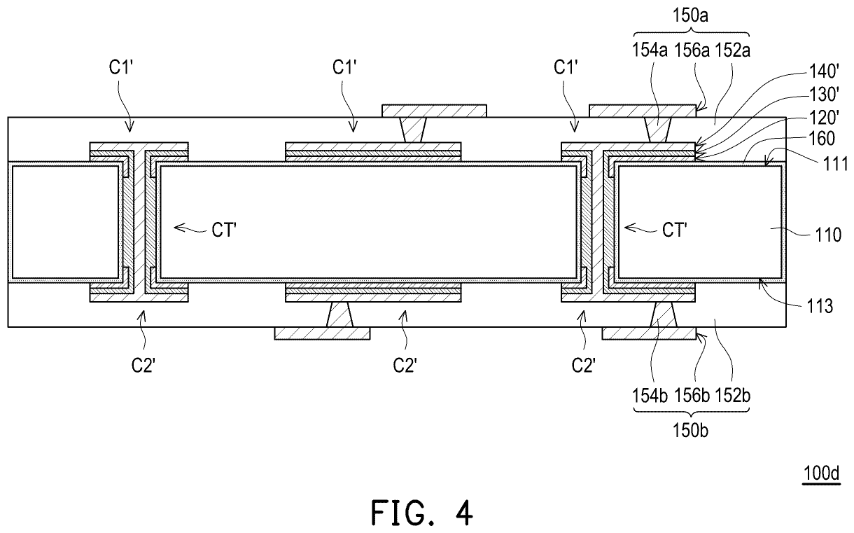

FIG. 4 is a cross-sectional schematic diagram of a substrate structure according to another embodiment of the disclosure. Referring to FIGS. 3D and 4, a substrate structure 100d in this embodiment is similar to the substrate structure 100c described above. However, the main difference between the two lies in that, in this embodiment, after patterning the conductive material 140′, the electroless metal layer 130′, and the sputtered metal layer 120′, at least one build-up structure (two build-up structures 150a and 150b are schematically illustrated) is formed on at least one of the upper surface 111 and the lower surface 113 of the core substrate 110 (schematically formed on the upper surface 111 and the lower surface 113, respectively). The build-up structure 150a includes at least one insulating layer (an insulating layer 152a is schematically illustrated), at least one conductive blind via (two conductive blind vias 154a are schematically illustrated), and at least one circuit (two circuits 156a are schematically illustrated). The insulating layer 152a covers the first conductive circuit C1. The circuit 156a is located on the insulating layer 152a. The conductive blind via 154a is located in the insulating layer 152a and electrically connected to the circuit 156a and the first conductive circuit C1. Similarly, the build-up structure 150b includes at least one insulating layer (one insulating layer 152b is schematically illustrated), at least one conductive blind via (two conductive blind vias 154b are schematically illustrated), and at least one circuit (two circuits 156b are schematically illustrated). The insulating layer 152b covers the second conductive circuit C2. The circuit 156b is located on the insulating layer 152b, and the conductive blind via 154b is located in the insulating layer 152b and electrically connected to the circuit 156b and the second conductive circuit C2. Through the arrangement of the build-up structures 150a and 150b, a fan-out structure can be formed, thereby enhancing the applicability of the substrate structure 100d.

In summary, the substrate structure and the manufacturing method thereof of the disclosure first form the sputtered metal layer on the upper surface, the lower surface, and a portion of the inner wall of the through-holes of the core substrate through a dry process. Subsequently, a wet process is performed to form the electroless metal layer on the sputtered metal layer and on the remaining portion of the inner wall of the through-holes. This approach addresses the issue of low step coverage encountered in the dry deposition process in the prior art, thereby allowing the substrate structure of the disclosure to have improved structural reliability.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A substrate structure, comprising:
a core substrate, having an upper surface and a lower surface opposite to each other, and at least one through-hole penetrating from the upper surface to the lower surface;
a sputtered metal layer, configured on the upper surface, the lower surface, and a portion of an inner wall of the at least one through-hole of the core substrate;
an electroless metal layer, configured on the sputtered metal layer and a remaining portion of the inner wall of the at least one through-hole; and
a conductive material layer, configured on the electroless metal layer and filling the at least one through-hole to define at least one first conductive circuit located on the upper surface, at least one second conductive circuit located on the lower surface, and at least one conductive through-hole located in the at least one through-hole and electrically connected to the at least one first conductive circuit and the at least one second conductive circuit.

2. The substrate structure according to claim 1, further comprising:
an adhesion promotion layer, directly covering the upper surface, the lower surface, and the inner wall of the at least one through-hole of the core substrate, wherein the sputtered metal layer is located between the adhesion promotion layer and the electroless metal layer.

3. The substrate structure according to claim 2, wherein a material of the adhesion promotion layer comprises an oxide or a nitride.

4. The substrate structure according to claim 3, wherein the oxide comprises a silicon oxide, an aluminum oxide, or a titanium oxide.

5. The substrate structure according to claim 3, wherein the nitride comprises a silicon nitride.

6. The substrate structure according to claim 2, wherein a thickness of the adhesion promotion layer is between 0.01 nanometers and 100 nanometers.

7. The substrate structure according to claim 1, wherein the core substrate comprises an insulating substrate.

8. The substrate structure according to claim 7, wherein the insulating substrate comprises an inorganic substrate.

9. The substrate structure according to claim 8, wherein a material of the inorganic substrate comprises a glass or a ceramic.

10. The substrate structure according to claim 1, wherein a surface roughness of the core substrate is between 1 nanometer and 50 nanometers.

11. The substrate structure according to claim 1, wherein a thickness of the core substrate is between 50 micrometers and 1000 micrometers.

12. The substrate structure according to claim 1, wherein a diameter of the at least one through-hole is between 10 micrometers and 200 micrometers.

13. The substrate structure according to claim 1, wherein a thickness of the electroless metal layer is less than 1 micrometer.

14. The substrate structure according to claim 1, wherein a material of the electroless metal layer comprises a nickel-phosphorus, a copper, a silver, or a combination thereof.

15. The substrate structure according to claim 1, wherein a material of the sputtered metal layer comprises a titanium-copper alloy.

16. The substrate structure according to claim 1, further comprising:
at least one build-up structure, configured on at least one of the upper surface and the lower surface of the core substrate, the at least one build-up structure comprising at least one insulating layer, at least one conductive blind via, and at least one circuit, wherein the at least one insulating layer covers at least one of the at least one first conductive circuit and the at least one second conductive circuit, the at least one circuit is located on the at least one insulating layer, and the at least one conductive blind via is located in the at least one insulating layer and electrically connected to the at least one circuit and the at least one of the at least one first conductive circuit and the at least one second conductive circuit.

17. A manufacturing method of a substrate structure, comprising:
providing a core substrate, the core substrate having an upper surface and a lower surface opposite to each other and at least one through-hole penetrating from the upper surface to the lower surface;
performing a dry process on the core substrate to form a sputtered metal layer on the upper surface, the lower surface, and a portion of an inner wall of the at least one through-hole of the core substrate;
performing a wet process on the core substrate to form an electroless metal layer on the sputtered metal layer and a remaining portion of the inner wall of the at least one through-hole;
forming a conductive material layer on the electroless metal layer, the conductive material layer filling the at least one through-hole to define at least one conductive through-hole in the at least one through-hole; and
patterning the conductive material layer, the electroless metal layer, and the sputtered metal layer to define at least one first conductive circuit on the upper surface of the core substrate and at least one second conductive circuit on the lower surface of the core substrate, wherein the at least one conductive through-hole is electrically connected to the at least one first conductive circuit and the at least one second conductive circuit.

18. The manufacturing method of the substrate structure according to claim 17, further comprising:
before performing the dry process on the core substrate, forming an adhesion promotion layer directly covering the upper surface, the lower surface, and the inner wall of the at least one through-hole of the core substrate.

19. The manufacturing method of the substrate structure according to claim 18, wherein a material of the adhesion promotion layer comprises an oxide or a nitride.

20. The manufacturing method of the substrate structure according to claim 17, further comprising:
after patterning the conductive material, the electroless metal layer, and the sputtered metal layer, forming at least one build-up structure on at least one of the upper surface and the lower surface of the core substrate, the at least one build-up structure comprising at least one insulating layer, at least one conductive blind via, and at least one circuit, wherein the at least one insulating layer covers at least one of the at least one first conductive circuit and the at least one second conductive circuit, the at least one circuit is located on the at least one insulating layer, and the at least one conductive blind via is located in the at least one insulating layer and electrically connected to the at least one circuit and the at least one of the at least one first conductive circuit and the at least one second conductive circuit.
